(19) United States
(12) Patent Application Publication
(10) Pub. No.: US 2007/0210441 A1
(43) Pub. Date: Sep. 13, 2007

(54) Microelectronic device assemblies including assemblies with recurved leadframes, and associated methods

(75) Inventors: David J. Corisis, Nampa, ID (US); Chin Hui Chong, Singapore (SG); Choon Kuan Lee, Singapore (SG)

Correspondence Address: PERKINS COIE LLP;PATENT-SEA, PO BOX 1247, SEATTLE, WA, 98111-1247, US

(73) Assignee: Micron Technology, Inc., Boise, ID (US)

(21) Appl. No.: 11/453,464

(22) Filed: Jun. 14, 2006

(30) Foreign Application Priority Data
Mar. 8, 2006 (SG) 200601518-4

(51) Int. Cl. H01L 23/12

(52) U.S. Cl. 257/700; 257/E25.013

(57) ABSTRACT

Microelectronic device assemblies, including assemblies with recurved leadframes, and associated methods are disclosed. An assembly in accordance with one embodiment includes a microelectronic device having a first surface, a second surface facing opposite from the first surface, and a plurality of bond sites accessible from the first surface. An operable microelectronic feature can be located between the first and second surfaces. The assembly can further include a leadframe positioned proximate to the microelectronic device, with the leadframe having a plurality of conductive leadfingers, each being electrically coupled to a corresponding bond site of the microelectronic device, and extending around the microelectronic device to face toward the second surface. This arrangement can be used to support single microelectronic devices, and/or stacked microelectronic devices.

### CROSS-REFERENCE TO RELATED APPLICATION

This application claims foreign priority benefits of Singapore Application No. 200601518-4 filed Mar. 8, 2006, which is incorporated herein by reference in its entirety.

### TECHNICAL FIELD

The present disclosure is directed generally to microelectronic device assemblies, including those with recurved leadframes, as well as associated methods.

### BACKGROUND

Packaged microelectronic assemblies, such as memory chips and microprocessor chips, typically include a microelectronic die mounted to a substrate and encased in a plastic protective covering. The die includes functional features, such as memory cells, processor circuits and interconnecting circuitry. The die also typically includes bond pads electrically coupled to the functional features. The bond pads are electrically connected to pins or other types of terminals that extend outside the protective covering for connecting the die to busses, circuits, and/or other microelectronic assemblies.

In one conventional arrangement, the die is mounted to a supporting substrate (e.g., a printed circuitboard), and the die bond pads are electrically coupled to corresponding bond pads of the substrate with wire bonds. After encapsulation, the substrate can be electrically connected to external devices, e.g., with solder balls. Accordingly, the substrate supports the die and provides an electrical link between the die and the external devices.

In other conventional arrangements, the die can be mounted to a leadframe that has conductive leadfingers connected to a removable frame that temporarily supports the leadfingers in position relative to the die during manufacture. Each leadfinger is wire bonded to a corresponding bond pad of the die, and the assembly is encapsulated in such a way that the frame and a portion of each of the leadfingers extends outside the encapsulating material. The frame is then trimmed off, and the exposed portions of each leadfinger can be bent to form pins for connecting the die to external components.

Die manufacturers have come under increasing pressure to reduce the size of their dies and the volume they occupy, and to increase the capacity of the resulting encapsulated assemblies. One approach to addressing these issues has been to stack multiple dies on top of each other so as to make increased use of the limited surface area on the circuitboard or other element to which the dies are mounted. One potential drawback with some of these mounting techniques is that they can be relatively expensive to produce. For example, mounting dies to a circuitboard or using a conductive tape to transmit signals to/from the dies can add cost to the production of stacked dies, due at least in part to the raw material cost of the circuitboard and the tape. Accordingly, there is a need for more efficient, lower cost methods for forming die assemblies, including assemblies having multiple stacked dies.

### BRIEF DESCRIPTION OF THE DRAWINGS

FIG. 1 is a cross-sectional side view of an assembly having a die and multiple leadframes configured in accordance with an embodiment of the invention.

FIG. 2 is a cross-sectional side view of an assembly that includes stacked dies, each connected to multiple leadframes in accordance with an embodiment of the invention.

FIG. 3A illustrates two leadframes configured in accordance with an embodiment of the invention.

FIGS. 3B-3E illustrate a method for connecting leadframes to a microelectronic die in accordance with an embodiment of the invention.

### DETAILED DESCRIPTION

The present disclosure relates generally to microelectronic device assemblies, including assemblies having recurved leadframes, and associated methods for forming and using such assemblies. An assembly in accordance with a particular aspect includes a microelectronic device having a first surface, a second surface facing opposite from the first surface, and a plurality of bond sites (e.g., bond pads) accessible from the first surface. The microelectronic device can further include an operable microelectronic feature (e.g., a memory element) between the first and second surfaces. The assembly can further include a leadframe positioned proximate to the microelectronic device. The leadframe can have a plurality of conductive leadfingers, with each leadfinger being electrically coupled to a corresponding bond site of the microelectronic device, and extending around (e.g., wrapped or recurved around) the microelectronic device to face toward the second surface.

In another aspect, the assembly can include multiple, stacked microelectronic devices. Accordingly, the microelectronic device described above can be a first microelectronic device having first bond sites. Each leadfinger can have a first portion electrically connected to a corresponding first bond site, and a second portion adjacent to the second face of the first microelectronic device. The assembly can further comprise a second microelectronic device positioned adjacent to the second portions of the leadfingers, with the leadfingers positioned between the first and second microelectronic devices. The second microelectronic device can have second bond sites electrically coupled to the second portions of leadfingers.

Still further aspects are directed to connection devices for microelectronic assemblies. One such device can include a self-supporting, electrically conductive support member that is elongated along an axis. The support member can have a first end spaced apart from a second end so that the support member does not completely enclose a space. A plurality of conductive leadfingers can be integrally formed with the support member and can extend away from the axis. In a further particular aspect, the support member is elongated along a first axis and each leadfinger has at least two bond sites, each positioned to receive a volume of solder. Each leadfinger can have a configuration that is mirrored about a second axis spaced apart from, and generally parallel to, the first axis.

Still another aspect is directed to a method for making a microelectronic assembly. One such method can include attaching a leadframe to bond sites accessible from a first surface of the microelectronic device, and arranging the leadfingers to extend around the microelectronic device and face toward a second surface of the microelectronic device that faces generally opposite from the first surface. In further particular aspects, arranging the leadfingers can include plastically deforming the leadfingers, for example, by bending the leadfingers. In particular embodiments, the leadfingers can be plastically overbent so as to bear against a portion of an encapsulant that is adjacent to the second surface of the microelectronic device. In still further aspects, multiple leadframes can be attached to the same microelectronic device and arranged so that the leadfingers of each leadframe extend around the microelectronic device and face toward the second surface.

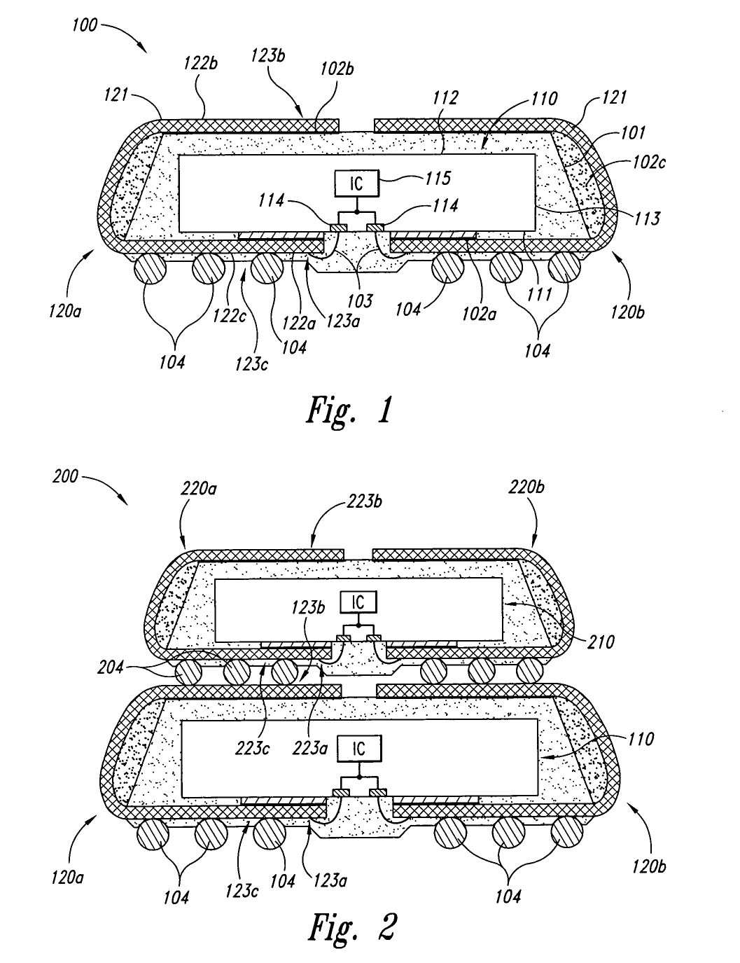

Many specific details of certain embodiments of the invention are set forth in the following description and in FIGS. 1-3D to provide a thorough understanding of these embodiments. One skilled in the art, however, will understand that the present invention may have additional embodiments, and that the invention may be practiced without several of the details described below.

FIG. 1 is a cross-sectional side view of an assembly 100 configured in accordance with an embodiment of the invention. The assembly 100 can include a microelectronic device 110 (e.g., a microelectronic die). The microelectronic device 110 can provide a wide variety of functions, including memory, processor and/or other functions. Accordingly, the microelectronic device 110 can include internal microelectronic features 115 (e.g., memory cells, capacitors, processor elements, and/or other integrated circuits) that are electrically coupled to device bond sites 114 (e.g., bond pads). Two leadframes 120 (shown as a first lead frame 120a and a second leadframe 120b) can be coupled to the device bond sites 114 to provide for electrical communication between the microelectronic device 110 and devices external to the microelectronic device 110. The external devices can include, but are not limited to, other microelectronic dies, including stacked dies, as will be described further below. As will also be described below, the leadframes 120 can perform other functions in addition to providing electrical communication with the microelectronic device 110.

The microelectronic device 110 can include a first surface 111 and a second surface 112 facing away from the first surface 111. The device bond sites 114 can be accessible via the first surface 111. For example, the device bond sites 114 can include bond pads that are flush with the first surface 111, recessed from the first surface 111, or that project from the first surface 111. In any of these arrangements, the leadframes 120 can be attached to the first surface 111 (e.g., with tape or another type of adhesive 102a) and can include multiple leadfingers 121 that extend proximate to the device bond sites 114. The multiple leadfingers 121 are arranged behind each other in a direction perpendicular to the plane of FIG. 1. Accordingly, only one leadfinger 121 of each of the leadframes 120a, 120b is visible in FIG. 1.

Each of the leadfingers 121 can include a first portion 122a having a first bond site 123a that is electrically connected to a corresponding one of the device bond sites 114. For example, each of the first bond sites 123a can be connected to a corresponding device bond site 114 with a wire bond 103. The electrical connection between the leadfingers 121 and the device bond sites 114 can be protected with an encapsulant 101 that also extends around the rest of the microelectronic device 110. Accordingly, the encapsulant 101 can envelope and protect the second surface 112 as well as the first surface 111 of the microelectronic device 110.

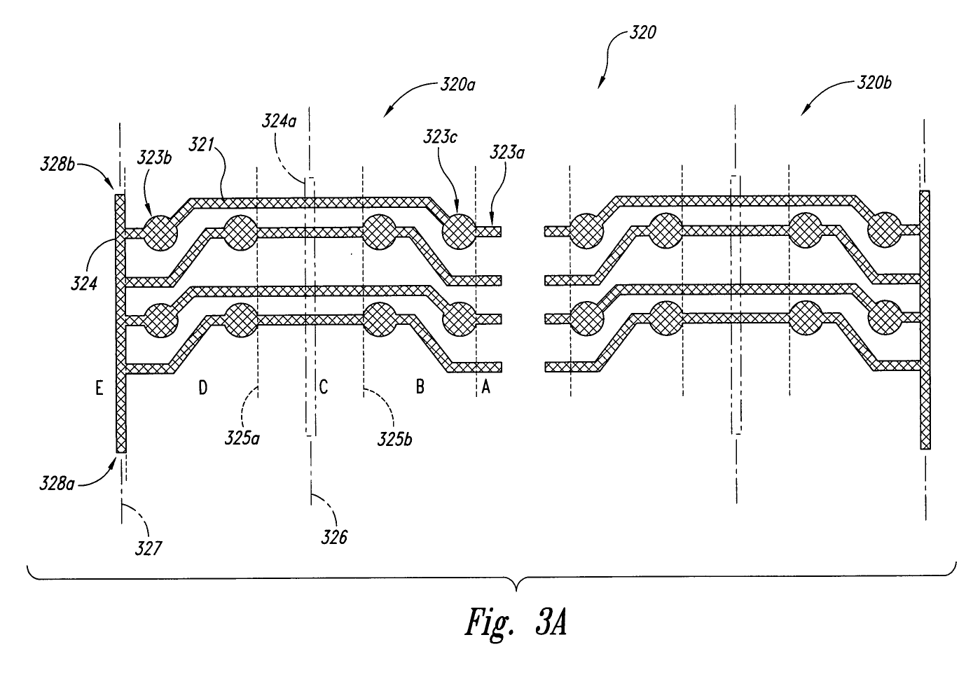

Each of the leadfingers 121 can be wrapped around the microelectronic device 110 so as to face toward the second surface 112, with the encapsulant 101 positioned between the second surface 112 and a second portion 122b of the leadfinger 121. The second portion 122b of the leadfinger 121 can include a second bond site 123b that is suitable for electrical connections to other stacked microelectronic devices 110, as will be described later with reference to FIG. 2. In a particular embodiment, the second portion 122b of each leadfinger 121 can be secured to the encapsulant 101 with an adhesive 102b. Accordingly, each leadfinger 121 can have a surface facing toward the microelectronic device 110, with spaced apart quantities of adhesive attaching the leadfinger 121 to the oppositely-facing first and second surfaces 111, 112. In other embodiments, the adhesive 102b at the second surface 112 can be eliminated. Each leadfinger 121 can also extend around a side surface 113 of the microelectronic device 110, located between the first and second surfaces 111, 112. An optional additional adhesive 102c can be provided between the leadfingers 121 and the portion of the encapsulant 101 that is adjacent to the side surface 113. Such an additional adhesive 102c can provide an additional securing force between the encapsulant 101 and the leadfinger 121, and/or can prevent contaminants from becoming lodged between the leadfinger 121 and the encapsulant 101 in this region.

Each leadfinger 121 can also include a third portion 122c located between the first portion 122a and the second portion 122b. The third portion 122c can have a third bond site 123c positioned to provide for electrical connections between the microelectronic device 110 and external devices. In a particular aspect of this embodiment, solder balls 104 can be positioned at the third bonding sites 123c to facilitate such connections. The third bond sites 123c of leadfingers 121 behind the plane of FIG. 1 can be laterally offset from each other so that three columns of solder balls are visible on each of the leadframes 120a, 120b.

FIG. 2 illustrates a stacked die assembly 200 that includes a first microelectronic device 110 (configured generally similarly to the microelectronic device 110 shown in FIG. 1), and a second microelectronic device 210 stacked on the first microelectronic device 110. Accordingly, the first microelectronic device 110 can include first and second leadframes 120a, 120b that are wrapped around the first microelectronic device 110, and that have corresponding second bond sites 123b. The second microelectronic device 210 can also include first and second leadframes 220a, 220b that wrap around it and that include first, second and third bond sites 223a, 223b, and 223c located in a fashion generally similar to that of the corresponding bond sites of the first microelectronic device 110. The second microelectronic device 210 can be electrically coupled to the first microelectronic device 110 with solder balls 204 (or other electrical couplers) that are connected between the first bond sites 223a of the second microelectronic device 210 and the second bond sites 123b of the first microelectronic device 110. In a particular aspect of this embodiment, the second microelectronic device 210 can be smaller than the first microelectronic device 110, as shown in FIG. 2. In other embodiments, the second microelectronic device 210 can be the same size as or larger than the first microelectronic device 110. In any of these embodiments, the electrical connections between the two microelectronic devices 110, 210 can be formed at portions of the leadframes 120a, 120b that wrap around the first microelectronic device 110.

As described above, one feature of an arrangement of the assemblies shown in FIGS. 1 and 2 is that they can include leadframes that wrap or recurve around the corresponding microelectronic dies. One expected advantage associated with this arrangement is that it can facilitate electrically coupled, stacked dies using a connection technique that may be less expensive than other connection techniques used for stacked dies. For example, manufacturing packaged dies with leadframes is typically less expensive than manufacturing packaged dies with circuitboards or conductive tape. Another expected advantage of at least some embodiments of this arrangement is that the leadfingers of the leadframes wrapped around the microelectronic devices tend to be longer and wider than typical wire traces and can accordingly be more effective at transmitting heat away from the microelectronic die to which they are attached. This benefit is expected to apply to both stand-alone dies having such leadfingers, and stacked dies that are coupled to each other with such leadfingers.

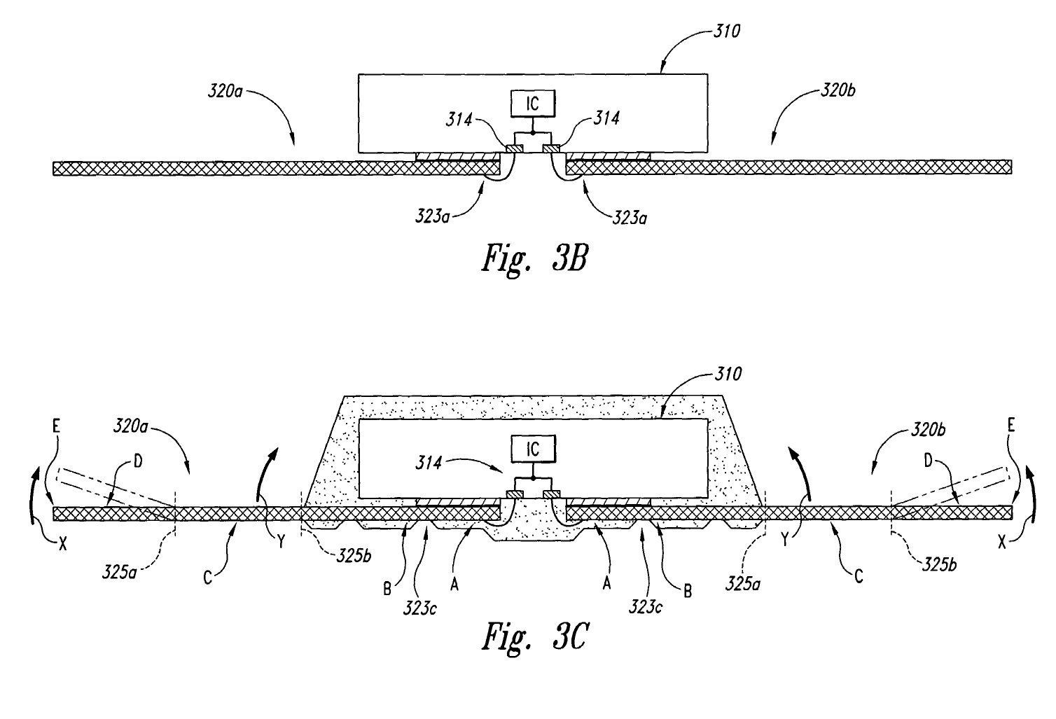

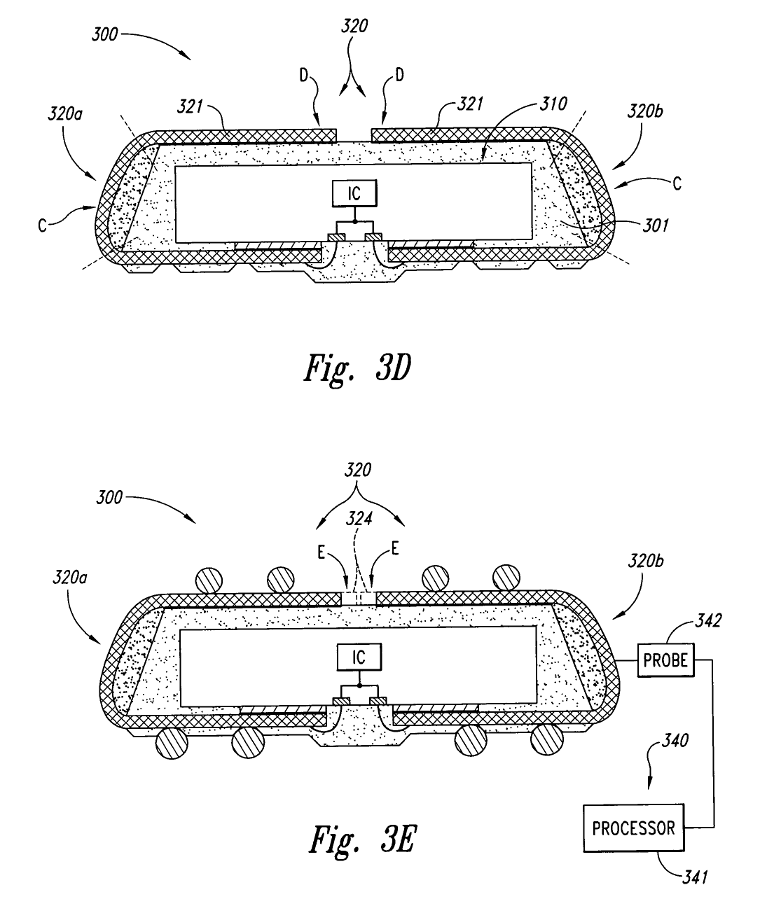

Still another feature of at least some embodiments of the assemblies shown in FIGS. 1 and 2 is that the leadfingers can be exposed alongside the side surfaces 113 of the microelectronic devices. As will be described later with reference to FIG. 3D, the exposed leadfingers can facilitate electrical testing of the dies to which they are attached.

FIG. 3A illustrates, in plan view, portions of first and second leadframes 320a, 320b referred to collectively as leadframes 320. The leadframes 320 are generally similar to the first and second leadframes 120a, 120b described above with reference to FIG. 1, but are each configured to have staggered bond sites that align to form columns along two axes rather than three axes. The second leadframe 320b may be generally similar to (and in the embodiment shown in FIG. 3A, a mirrored version of) the first leadframe 320a. Accordingly, most if not all aspects of the following discussion regarding the first leadframe 320a apply to the second leadframe 320b as well.

The first leadframe 320a can have multiple leadfingers 321, each with a first bond site 323a, a second bond site 323b, and a third bond site 323c. Each of the leadfingers 321 can be attached to a support member 324. The support member 324 can be elongated along a support member axis 327 and can include a first end 328a spaced apart from a second end 328b. For purposes of illustration, the first leadframe 320a is shown with four leadfingers 321. It will be understood by those of ordinary skill in the art that in other embodiments, the first leadframe 320a can include more (or fewer) leadfingers 321. In any of these embodiments, the first and second ends 328a, 328b of the support member 324 can be spaced apart from each other so that the support member 324 does not completely enclose a space. This is unlike typical leadframes in which the support member forms an enclosed shape from which the leadfingers depend.

The first leadframe 320a can include five regions identified by letters A-E, respectively. Region A can include the first bond site 323a configured to be electrically coupled to a microelectronic device. Region B can include the third bond site 323c suitable for coupling to external devices. Region C may not include any bond sites, but may be used to facilitate device testing as described in greater detail below. Region C can optionally include an additional support member 324a. Region D can include the second bond site 323b positioned for attaching to stacked microelectronic devices, as described above with reference to FIG. 2. Region E can include the support member 324, which can maintain the proper positioning between the leadfingers 321 as the leadframe is attached to the corresponding microelectronic device. The support member 324 (and the optional additional support member 324a) can be removed after the leadfingers 321 are attached to the microelectronic device, as described later.

The first leadframe 320a can be formed from a conventional leadframe material (e.g., copper or an iron/nickel alloy) and can be self-supporting (e.g., it can maintain its shape). The first leadframe 320a can be foldable along a first fold line 325a between regions C and D, and a second fold line 325b between regions C and B. In a particular aspect of an embodiment shown in FIG. 2, the leadfingers 321 (but not the support member 324) can be generally symmetrical about a symmetry line 326. Accordingly, when the first leadframe 320a is folded around a microelectronic device, the third bond sites 323c can be positioned over the second bond sites 323b.

FIG. 3B illustrates the first and second leadframes 320a, 320b positioned proximate to a microelectronic device 310 in accordance with an embodiment of the invention. In one aspect of this embodiment, the first bond sites 323a of each of the leadframes 320 are positioned proximate to corresponding die bond sites 314, and attached to the die bond sites 314 with wire bonds or other electrical couplers. After the leadframes 320 have been attached to the microelectronic device 310 with an adhesive (e.g., tape), and coupled to the die bond sites 314, the assembly 300 can be encapsulated with an encapsulant 301 (FIG. 3C). Appropriate pins may be positioned in the encapsulating mold to prevent the encapsulant 301 from attaching to regions (e.g., the third bond sites 323c) that are to be exposed for electrical coupling to other devices.

After the microelectronic device 310 has been encapsulated, the leadframes 320 can be folded along the first fold line 325a and the second fold line 325b. In a particular aspect of this embodiment, each leadframe 320 can be folded along the first fold line 325a (as indicated by arrow X) and subsequently folded along the second fold line 325b (as indicated by arrow Y). In other embodiments, the order in which the leadframes 320 are folded can be reversed.

FIG. 3D illustrates an assembly 300 after the leadframes 320 have been folded over the encapsulant 301. In one aspect of this embodiment, region D of the leadframes 320 can be bonded directly to the encapsulant 301. For example, region D can be bonded with an adhesive. In another embodiment, the encapsulant 301 can be softened and region D can be pressed into the encapsulant 301, after which the encapsulant 301 can be cooled and/or cured. In still a further embodiment, region D need not be attached directly to the encapsulant 301. Instead, region D can rest on the encapsulant 301. In yet a further embodiment, the leadframes 320 can be “overbent” so that region D of each leadframe 320 bears resiliently against the encapsulant 301. In any of these embodiments, the lower corner of the encapsulant 301 can act as a pivot point about which the leadfingers 321 are bent. As described above, region C, which aligns alongside the sides of the encapsulant 301, can also be directly attached to the encapsulant 301, or can remain detached.

FIG. 3E illustrates the resulting assembly 300 after the leadframes 320 have been folded and solder balls 204 have been attached to the leadframes 320. As is also shown in FIG. 3E, the support members 324 (indicated in dashed lines) have been trimmed so as to allow for independent signal paths to the leadfingers 321. Any suitable technique (e.g., laser cutting or grinding) can be used to remove the support members 324. If the leadframes 320 include additional support members 324a (FIG. 3A), these additional support members can also be trimmed. When the resulting assembly 300 is to be used in a stacked die configuration, a second microelectronic die can be attached to the leadframes 320, as was described above with reference to FIG. 2. Whether or not the assembly 300 includes a stacked die, the leadframes 320 can provide for electrical communication with external devices, as was also described above.

One feature of die packages in accordance with several embodiments described above is that they can make use of several existing die packaging techniques to provide an improved package. For example, existing equipment may be used to position the leadframes and wire bond them to the corresponding die bond pads, with little or no modification. The use of existing, generally low-cost manufacturing equipment can control and/or reduce the cost of manufacturing the described assemblies, when compared to other manufacturing techniques.

Another feature of several embodiments described above is that they can include leadfingers that are wrapped around the encapsulated die. As a result, the side portions of the leadfingers (e.g., region C) remain exposed, even if the assembly includes stacked dies. If the assembly includes a single die, the top portion of the leadfingers 321 (e.g., region D) may also be exposed. An advantage of the exposed portions of the leadfingers 321 is that they can facilitate access to the assembly for testing. For example, a test device 340 (shown schematically in FIG. 3E) can include a processor 341 coupled to a probe 342. An operator can position the probe 341 to contact each of the leadfingers 321 for testing, even after the assembly is attached to external devices, and/or further manufactured to include stacked dies.

From the foregoing, it will be appreciated that specific embodiments of the invention have been described herein for purposes of illustration, but that various modifications may be made without deviating from the scope of the invention. For example, the microelectronic devices can have configurations other than those shown in the Figures. In particular embodiments, electrical couplings other than the wire bonds and/or solder balls shown in the Figures can be used to couple the microelectronic device to the leadframe and/or other devices. Although advantages associated with certain embodiments of the invention have been described in the context of those embodiments, other embodiments may also exhibit such advantages. Additionally, none of the foregoing embodiments need necessarily exhibit such advantages to fall within the scope of the invention. Accordingly, the invention is not limited except as by the appended claims.

I/We claim:

1. A microelectronic assembly, comprising:
a microelectronic device having a first surface, a second surface facing opposite from the first surface, a plurality of bond sites accessible from the first surface, and an operable microelectronic feature between the first and second surfaces; and
a leadframe positioned proximate to the microelectronic device, the leadframe having a plurality of conductive leadfingers, each leadfinger being electrically coupled to a corresponding bond site of the microelectronic device and extending around the microelectronic device to face toward the second surface.

2. The assembly of claim 1 wherein the microelectronic device includes a microelectronic die.

3. The assembly of claim 1 wherein the leadframe is one of two separate leadframes positioned proximate to and electrically coupled to the microelectronic device.

4. The assembly of claim 1, further comprising an encapsulant at least partially surrounding the microelectronic device, and wherein a portion of the encapsulant is positioned between the microelectronic device and the leadframe.

5. The assembly of claim 4 wherein the microelectronic device has a side surface between the first and second surfaces, and wherein a side portion of the encapsulant is positioned adjacent to the side surface of the microelectronic device and wherein the leadframe is not attached directly to the side portion of the encapsulant.

6. The assembly of claim 4 wherein the microelectronic device has a side surface between the first and second surfaces, and wherein a side portion of the encapsulant is positioned adjacent to the side surface of the microelectronic device and wherein the leadframe is attached directly to the side portion of the encapsulant.

7. The assembly of claim 4 wherein the leadframe resiliently bears against the encapsulant adjacent to the second surface.

8. The assembly of claim 4 wherein the leadframe is attached to the encapsulant adjacent to the second surface.

9. The assembly of claim 4 wherein the leadframe is attached to the encapsulant adjacent to the second surface with an epoxy.

10. The assembly of claim 4 wherein the leadfingers are positioned external to the encapsulant at a location where the leadfingers face toward the second surface of the microelectronic device with a portion of the encapsulant positioned between and in contact with the second surface of the microelectronic device and the leadfingers.

11. The assembly of claim 1 wherein the microelectronic device is a first microelectronic device, the bond sites are first bond sites, and each leadfinger has a first portion electrically connected to a corresponding first bond site and a second portion adjacent to the second surface, and wherein the assembly further comprises:
a second microelectronic device positioned adjacent to the second portions of the leadfingers with the leadfingers positioned between first and second microelectronic devices, the second microelectronic device having second bond sites electrically coupled to the second portions of the leadfingers.

12. The assembly of claim 1 wherein the microelectronic device is attached to the leadfingers with wire bonds, and wherein the leadfingers include solder balls positioned for coupling to other devices.

13. The assembly of claim 1 wherein the microelectronic device is not electrically connected to a flexible conductive tape.

14. A microelectronic assembly, comprising:
a first microelectronic device having a first surface, a second surface facing opposite from the first surface, a plurality of first bond sites accessible from the first surface, and an operable microelectronic feature between the first and second surfaces;
a leadframe having a plurality of conductive leadfingers, each leadfinger extending around the device from the first surface to the second surface, each leadfinger having a first portion electrically connected to a corresponding first bond site and a second portion adjacent to the second surface; and
a second microelectronic device positioned adjacent to the second portions of the leadfingers with the leadfingers positioned between first and second microelectronic devices, the second microelectronic device having second bond sites electrically coupled to the second portions of the leadfingers.

15. The assembly of claim 14 wherein the first and second microelectronic devices have generally identical configurations.

16. The assembly of claim 14 wherein the first and second microelectronic devices have different configurations.

17. The assembly of claim 14 wherein the first and second microelectronic devices have different sizes.

18. The assembly of claim 14 wherein the first portion of each leadfinger is coupled to the corresponding first bond site with a wire bond, and wherein the second portion of each leadfinger is coupled to the corresponding second bond site with a solder ball, and wherein each leadfinger includes a third portion between the first and second portions, the third portion carrying a solder ball positioned for attachment to an external device.

19. The assembly of claim 14 wherein the first and second microelectronic devices each include a microelectronic die.

20. The assembly of claim 14, further comprising an encapsulant at least partially surrounding the first microelectronic device, and wherein a portion of the encapsulant is positioned between the first microelectronic device and the leadframe.

21. The assembly of claim 20 wherein the first microelectronic device has a side surface between the first and second surfaces, and wherein a side portion of the encapsulant is positioned adjacent to the side surface of the first microelectronic device and wherein the leadframe is not attached directly to the side portion of the encapsulant.

22. The assembly of claim 20 wherein the first microelectronic device has a side surface between the first and second surfaces, and wherein a side portion of the encapsulant is positioned adjacent to the side surface of the first microelectronic device and wherein the leadframe is attached directly to the side portion of the encapsulant.

23. The assembly of claim 20 wherein the leadframe resiliently bears against the encapsulant adjacent to the second surface.

24. The assembly of claim 20 wherein the leadframe is attached to the encapsulant adjacent to the second surface.

25. The assembly of claim 20 wherein the leadfingers are positioned external to the encapsulant at a location where the leadfingers face toward the second surface of the microelectronic device with a portion of the encapsulant positioned between and in contact with the second surface of the microelectronic device and the leadfingers.

26. The assembly of claim 14 wherein the first microelectronic device is not electrically connected to a flexible conductive tape.

27. The assembly of claim 14 wherein the leadframe is one of two separate leadframes positioned proximate to and electrically coupled to the first microelectronic device.

28. A connecting device for microelectronic assemblies, comprising:
a self-supporting, electrically conductive support member, the support member being elongated along an axis, the support member having a first end spaced apart from a second end so that the support member does not completely enclose a space; and
a plurality of conductive leadfingers integrally formed with the support member and extending away from the support member.

29. The device of claim 28 wherein the support member has an at least generally straight shape.

30. The device of claim 28 wherein each leadfinger has a bond site positioned to receive a volume of solder.

31. The device of claim 28 wherein each leadfinger has at least two bond sites, each positioned to receive a volume of solder.

32. The device of claim 28 wherein each leadfinger includes a first bond site configured to received a wire bond connection, a second bond site spaced apart from the first bond site and configured to receive a solder ball, and a third bond site positioned between the first and second bond sites and configured to receive another solder ball.

33. The device of claim 28 wherein the support member is elongated along a first axis, and wherein each leadfinger has at least two bond sites, each positioned to receive a volume of solder, and wherein each leadfinger has a configuration that is mirrored about a second axis spaced apart from and generally parallel to the first axis.

34. The device of claim 28 wherein the support member is a first support member and wherein the device further comprises a second support member spaced apart from the first support member and connected to each of the leadfingers.

35. The device of claim 28 wherein the leadfingers are plastically deformable between a first generally self-supporting shape and a second generally self-supporting shape.

36. The device of claim 28 wherein each leadfinger has a first surface and a second surface facing opposite from the first surface, and wherein each leadfinger includes a first quantity of adhesive on the first surface and a second quantity of adhesive on the first surface and spaced apart from the first quantity of adhesive.

37. A method for making a microelectronic assembly, comprising:
attaching a leadframe to bond sites accessible from a first surface of a microelectronic device; and
arranging the leadfingers to extend around the microelectronic device and face toward a second surface of the microelectronic device, the second surface facing generally opposite from the first face.

38. The method of claim 37 wherein the leadframe is a first leadframe attached to a first set of bond sites, and wherein the method further comprises:
attaching a second leadframe that is separate from the first leadframe to a second set of bond sites of the microelectronic device; and
arranging leadfingers of the second leadframe to extend around the microelectronic device and face toward the second surface of the microelectronic device.

39. The method of claim 37 wherein arranging the leadfingers includes plastically deforming the leadfingers.

40. The method of claim 37 wherein arranging the leadfingers includes plastically bending the leadfingers.

41. The method of claim 37 wherein arranging the leadfingers includes plastically bending each of the leadfingers at a first location and at a second location spaced apart from the first location.

42. The method of claim 37 wherein the first surface of the microelectronic device faces in a first direction and wherein arranging the leadfingers includes bending the leadfingers in a second direction opposite the first direction.

43. The method of claim 37, further comprising at least partially encapsulating the microelectronic device.

44. The method of claim 43 wherein arranging the leadfingers includes plastically overbending the leadfingers so that the leadfingers bear against a portion of an encapsulant adjacent to the second surface of the microelectronic device.

45. The method of claim 43, further comprising attaching the leadfingers to a portion of an encapsulant adjacent to the second surface of the microelectronic device.

46. The method of claim 37 wherein the microelectronic device is a first microelectronic device and wherein the method further comprises stacking a second microelectronic device relative to the first microelectronic device and electrically coupling the second microelectronic device to the leadfingers.

47. The method of claim 46 wherein stacking a second microelectronic device includes stacking a second microelectronic device having a configuration different than a configuration of the first microelectronic device.

48. The method of claim 37 wherein arranging a leadframe includes arranging a leadframe having a support member that is elongated along an axis, with the leadfingers extending away from the support member, and wherein the support member has first and second ends spaced apart from each other so that the elongated member does not completely enclose a space.

49. The method of claim 48, further comprising removing the support member after arranging the leadfingers.

50. The method of claim 48 wherein arranging the leadfingers includes bending the leadfingers, and wherein the method further comprises removing the support member after bending the leadfingers.

51. The method of claim 48 wherein the support member is a first support member and wherein the leadframe has second support member spaced apart from the first support member and connected to each of the leadfingers, and wherein the method further comprises removing the first and second support members.

52. The method of claim 48 wherein each leadfinger has first and second bond sites and wherein arranging the leadfingers includes positioning each first bond site proximate to a corresponding bond site of the microelectronic device and wherein the method further comprises:
wirebonding each first bond site to the corresponding bond site of the microelectronic device; and
connecting a solder ball to each second bond site.

53. A method for testing a microelectronic assembly, comprising:
electrically coupling a testing device to a leadframe by contacting leadfingers of the leadframe that extend around a microelectronic device from a first face of the microelectronic device to a second face of the microelectronic device facing generally opposite from the first face; and
directing electrical signals between the testing device and the microelectronic device via the leadframe.

54. The method of claim 53 wherein the microelectronic device includes a microelectronic die at least partially enclosed by an encapsulant, and wherein the contacting the leadfingers includes contacting exposed portions of the leadfingers extending through the encapsulant.

55. The method of claim 53 wherein the microelectronic device includes a side surface between the first and second surfaces, and wherein contacting the leadfingers includes contacting the leadfingers at a location where the leadfingers are positioned alongside the side surface.

56. The method of claim 53 wherein contacting the leadfingers includes contacting the leadfingers at a location where the leadfingers are positioned alongside the second surface.

57. A method for making a microelectronic assembly, comprising:
attaching a first leadframe to first device bond sites of a microelectronic device;
attaching a second leadframe that is separate from the first leadframe to second device bond sites of the same microelectronic device; and
arranging leadfingers of the first and second leadframes for attachment to additional devices.

58. The method of claim 57 wherein attaching a second leadframe includes attaching a second leadframe that is at least generally a mirror image of the first leadframe.

59. The method of claim 57 wherein the first and second device bond sites are accessible from a first surface of the microelectronic device, and wherein arranging the leadfingers includes arranging the leadfingers to extend around the microelectronic device and toward a second surface of the microelectronic device, the second surface facing generally opposite from the first face.

60. The method of claim 57 wherein the microelectronic device is a first microelectronic device and wherein the method further comprises stacking a second microelectronic device relative to the first microelectronic device and electrically coupling the second microelectronic device to the leadfingers.

61. The method of claim 57 wherein arranging the leadfingers includes arranging the leadfingers of two leadframes, each having a support member that is elongated along an axis, with the leadfingers extending away from the support member, and wherein the support member has first and second ends spaced apart from each other so that the elongated member does not completely enclose a space.

62. The method of claim 61, further comprising removing the support member of each leadframe after arranging the leadfingers.
